(19) United States
(12) Patent Application Publication
(10) Pub. No.: US 2025/0316606 A1
(43) Pub. Date: Oct. 9, 2025

(54) THREE-DIMENSIONAL PACKAGE STRUCTURE AND METHOD FOR FORMING THE SAME

(71) Applicant: JCET Semiconductor (Suqian) Co., Ltd., Suqian (CN)

(72) Inventor: Sai XU, Suqian (CN)

(73) Assignee: JCET Semiconductor (Suqian) Co., Ltd., Suqian (CN)

(21) Appl. No.: 19/171,633

(22) Filed: Apr. 7, 2025

(30) Foreign Application Priority Data
Apr. 8, 2024 (CN) 202410413795.2

(51) Int. Cl. H01L 23/538; H01L 21/48; H01L 23/00; H01L 23/31; H01L 23/34; H01L 25/00; H01L 25/07

(52) U.S. Cl. CPC H01L 23/5386; H01L 21/4853; H01L 23/34; H01L 25/071; H01L 25/50; H01L 23/3107; H01L 24/48; H01L 2224/48137; H01L 2224/48145; H01L 2224/48227

(57) ABSTRACT

A three-dimensional package structure and a method for forming the same are provided. The three-dimensional package structure comprises: a carrier board; a first chip located on the top surface of the carrier board; a second chip located on the side of the first chip facing away from the carrier board, a conductive strip located on the carrier board, one end of the conductive strip being electrically connected to the second chip and the other end being electrically connected to the carrier board, the conductive strip comprising a bent part, the bent part comprising a first planar segment located in a first direction on the outside the second chip, the first direction being parallel to the first planar segment; and a third chip, mounted on the first planar segment.

### CROSS-REFERENCE TO RELATED APPLICATIONS

This application claims the benefit of priority to Chinese Application No. 202410413795.2, filed on Apr. 8, 2024, which is hereby incorporated by reference in its entirety.

### TECHNICAL FIELD

The present disclosure relates to the technical field of integrated circuit manufacturing, and particularly relates to a three-dimensional package structure and a method for forming the same.

### BACKGROUND

Currently, the semiconductor integrated circuit (IC) industry has experienced exponential growth. Technological advancements in IC materials and design have resulted in several generations of ICs, each of which has smaller and more complex circuits than the previous generation. During the development of IC, functional density (i.e., the number of interconnected devices per chip area) has generally increased, while geometric dimensions (i.e., the smallest part that can be produced using the manufacturing process) have continuously decreased. As Moore's Law has slowed, the semiconductor industry has turned toward three-dimensional (3D) chip stacking interconnection technology in order to continue to improve device performance.

A three-dimensional package structure refers to the technology of placing two or more chips within a single package body. Currently, some three-dimensional package structures realize the electrical connections between different chips, as well as between chips and pins, by vertically stacking multiple chips and utilizing bond wires and copper sheets, etc. However, copper sheets will occupy a larger space within the package body, thus reducing the space utilization rate within the package body, making the three-dimensional package structure unable to meet the integration of more package units and the extension of application scenarios.

### SUMMARY

According to some embodiments, the present disclosure provides a three-dimensional package structure, comprising: a carrier board; a first chip, located on a top surface of the carrier board; a second chip, located on the side of the first chip facing away from the carrier board; a conductive strip, located on the carrier board, one end of the conductive strip being electrically connected to the second chip and the other end being electrically connected to the carrier board, the conductive strip comprising a bent part, the bent part comprising a first planar segment located outside the second chip in a first direction, the first direction being parallel to the top surface of the carrier board; and a third chip, mounted on the first planar segment.

In some embodiments, in the first direction, the third chip is located outside the first chip.

In some embodiments, the carrier board comprises a base island and a first pin located outside the base island, the first pin having a recess in it.

In some embodiments, the conductive strip further comprises a first welding part located at the end of the bent part, the first welding part being at least partially inserted into the recess of the first pin and electrically connected to the first pin.

In some embodiments, the carrier board further comprises a plurality of second pins located outside the base island, at least a partial number of the second pins being distributed in the second direction on the side of the base island facing away from the first pin.

In some embodiments, the first chip is electrically connected to the second pin.

In some embodiments, the bent part of the conductive strip further comprises a second planar segment located above the second chip; the three-dimensional package structure further comprises: a sensor, mounted on the second planar segment, and the sensor being electrically connected to the carrier board.

In some embodiments, it further comprises: a molding layer, which molds the first chip, the second chip, the third chip, the conductive strip, and at least a partial of the sensor, and the detection end of the sensor is exposed outside the molding layer.

In some embodiments, it further comprises: a conductive connection pillar, one end of which is electrically connected to the first chip, and the other end is electrically connected to the sensor.

In some embodiments, it further comprises: a first bond wire, one end of which is electrically connected to the first chip and the other end is electrically connected to the carrier board; a second bond wire, one end of which is electrically connected to the second chip and the other end is electrically connected to the first chip; a third bond wire, one end of which is electrically connected to the third chip and the other end is electrically connected to the first chip.

According to other embodiments, the present disclosure also provides a method for forming a three-dimensional package structure, comprising the following steps: forming a carrier board; mounting a first chip onto a top surface of the carrier board; mounting a second chip onto the surface of the first chip facing away from the carrier board; mounting a conductive strip onto the carrier board, and one end of the conductive strip being electrically connected to the second chip and the other end being electrically connected to the carrier board, the conductive strip comprising a bent part, the bent part comprising a first planar segment located outside the second chip in a first direction, the first direction being parallel to the top surface of the carrier board; mounting a third chip onto the first planar segment.

In some embodiments, the carrier board comprises a base island and a first pin located outside the base island, the first pin having a recess in it; the specific steps of mounting a conductive strip onto the carrier board comprise: forming a conductive strip, the conductive strip further comprising a first welding part and a second welding part located at opposite ends of the bent part; inserting the first welding part into the recess in the first pin, electrically connecting the first welding part to the first pin and electrically connecting the second welding part to the second chip.

In some embodiments, the specific steps of mounting the third chip onto the first planar segment comprise: mounting the third chip onto the first planar segment such that the third chip is located outside the first chip in the first direction.

In some embodiments, the bent part in the conductive strip further comprises a second planar segment located above the second chip; the method for forming a three-dimensional package structure further comprises the following steps: mounting a sensor onto the second planar segment and electrically connecting the sensor to the carrier board.

In some embodiments, the specific steps of electrically connecting the sensor to the carrier board comprise: electrically connecting the sensor to one end of the conductive connection pillar, the other end of the conductive connection pillar being electrically connected to the first chip.

In some embodiments, after mounting the third chip onto the first planar segment, it further comprises the following steps: electrically connecting the first chip to the carrier board and electrically connecting the third chip to the carrier board.

In some embodiments, the carrier board further comprises a plurality of second pins located outside the base island, at least a partial number of the second pins being distributed in the second direction on the side of the base island facing away from the first pin; the specific steps of electrically connecting the first chip to the carrier board and electrically connecting the third chip to the carrier board comprise: forming a first bond wire electrically connecting the first chip to the second pin, forming a second bond wire electrically connecting the first chip to the second chip, and forming a third bond wire electrically connecting the first chip to the third chip.

In some embodiments, after electrically connecting the first chip to the carrier board, further comprising the following steps: forming a molding layer that molds the first chip, the second chip, the third chip, the conductive strip, and at least a partial of the sensor, and the detection end of the sensor is exposed outside the molding layer.

### BRIEF DESCRIPTION OF THE DRAWINGS

FIG. 1 is a schematic top view of the three-dimensional package structure in some embodiments of the present disclosure;

FIG. 2 is a schematic sectional view of the three-dimensional package structure in some embodiments of the present disclosure;

FIG. 3 is a flowchart of a method for forming the three-dimensional package structure in some embodiments of the present disclosure; and

FIGS. 4-10 are schematic diagrams of the main process structures of the process for forming the three-dimensional package structure in some embodiments of the present disclosure.

### DETAILED DESCRIPTION

Specific embodiments of the three-dimensional package structure and the method for forming the same provided by the present disclosure are described in detail below in conjunction with the accompanying drawings.

How to improve the space utilization rate within the three-dimensional package structure and improve the integration degree of the three-dimensional package structure to meet the demand for integration of more package units and the extension of application scenarios is a technical problem that urgently demands to be solved at present.

The present disclosure provides a package structure and a method for forming the same to improve the space utilization rate within the three-dimensional package structure and the integration degree of the three-dimensional package structure, in order to meet the demand for integration of more package units and the extension of application scenarios.

In the three-dimensional package structure and the method for forming the same provided by the present disclosure, through the conductive strip with a bent part electrically connecting the second chip and the carrier board, and by using the first planar segment in the bent part of the conductive strip as the mounting platform for the third chip, the third chip is mounted on the first planar segment; since the first planar segment is located outside the second chip in a direction parallel to the top surface of the carrier board (e.g., the first direction), thereby enabling the second chip and the third chip to be arranged in a direction parallel to the top surface of the carrier board, it not only makes full use of the internal space of the three-dimensional package structure, i.e., improves the space utilization rate inside the three-dimensional package structure. Moreover, by improving the space utilization rate inside the three-dimensional package structure, more semiconductor structures (e.g., chips, etc.) can also be integrated inside the three-dimensional package structure, thereby improving the integration degree of the three-dimensional package structure to meet the demand for integration of more package units as well as the extension of application scenarios.

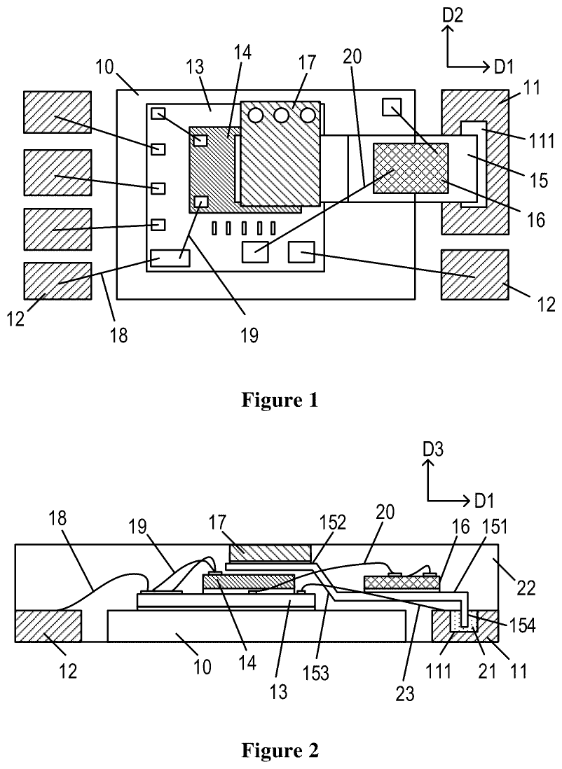

The present embodiment provides a three-dimensional package structure. FIG. 1 is a schematic top view of the three-dimensional package structure in some embodiments of the present disclosure, FIG. 2 is a schematic sectional view of the three-dimensional package structure in some embodiments of the present disclosure. As shown in FIGS. 1 and 2, the three-dimensional package structure comprises: a carrier board; a first chip 13, located on the top surface of the carrier board; a second chip 14, located on the side of the first chip 13 facing away from the carrier board; a conductive strip 15, located on the carrier board, one end of the conductive strip 15 being electrically connected to the second chip 14 and the other end being electrically connected to the carrier board, the conductive strip 15 comprising a bent part, the bent part comprising a first planar segment 151 located outside the second chip 14 in a first direction D1, the first direction DI being parallel to the top surface of the carrier board; and a third chip 16, mounted on the first planar segment 151.

Specifically, the carrier board may be a substrate. The carrier board comprises a top surface and a bottom surface distributed opposite each other in a third direction D3, and the first chip 13 may be mounted on the top surface of the carrier board by solder. The third direction D3 is perpendicular to the top surface of the carrier board. The second chip 14 is stacked on the top surface of the first chip 13 (i.e., the surface of the first chip 13 is facing away from the carrier board) in the third direction D3. The conductive strip 15 is used to bridge the second chip 14 with the carrier board, i.e., one end of the conductive strip 15 is bonded and electrically connected to the second chip 14, and the other end is bonded and electrically connected to the carrier board, so as to be able to realize the transmission of electrical signals between the second chip 14 and the carrier board by means of the conductive strip 15. By adopting the conductive strip 15 to realize the electrical connection between the second chip 14 and the carrier board, it is able to not only simplify the difficulty of the manufacturing process of the three-dimensional package structure and reduce the cost of the manufacturing process of the three-dimensional package structure, but also to help improve the thermal conductivity performance and current conduction performance of the three-dimensional package structure. In one example, the conductive strip 15 may be a copper strip. The structure of the first chip 13 and the second chip 14 may be the same or different. In one example, the first chip 13 may be a module chip or a functional chip for realizing one or more module functions; the second chip 14 is a control chip.

The conductive strip 15 in the present embodiment comprises the bent part, the bent part comprising the first planar segment 151 extending in a direction parallel to the top surface of the carrier board (e.g., the first direction D1), and a connection segment 153 connected to the first planar segment 151 and extending in a direction that intersects (e.g., intersects at an incline or perpendicularly) with the top surface of the carrier board. The third chip 13 is mounted on the surface of the first planar segment 151 facing away from the carrier board and the first planar segment 151 is located outside the second chip 14 in the first direction D1, thereby enabling the second chip 14 and the third chip 16 to be arranged in a direction (e.g., in the first direction D1) parallel to the top surface of the carrier board, so that the conductive strips 15 not only serve as a bridge connecting the second chip 14 to the carrier board, but also as a chip loading platform for the third chip 16, which not only fully utilizes the internal space of the three-dimensional package structure and improves the space utilization rate of the three-dimensional package structure, but also enables the integration of more chips (e.g., the third chip 16) within the three-dimensional package structure, thereby improving the integration degree of the three-dimensional package structure to meet the demand for integration of more package units as well as the extension of application scenarios. In one example, the structure of the third chip 16 may be the same as the structure of the second chip 14, such as both being control chips. In another example, the structure of the third chip 16 is different from the structure of the second chip 14 to further extend the functions of the three-dimensional package structure.

In some embodiments, the third chip 16 is located outside the first chip 13 in the first direction D1.

Specifically, the projection of the third chip 16 on the top surface of the carrier board is located outside the projection of the first chip 13 on the top surface of the carrier board, and the projection of the third chip 16 on the top surface of the carrier board is located outside the projection of the second chip 14 on the top surface of the carrier board, thereby not only making full use of the internal space of the three-dimensional package structure, but also helping reduce the parasitic capacitance effects between the third chip 16 and the first chip 13 as well as the parasitic capacitance effects between the third chip 16 and the second chip 14.

In some embodiments, the carrier board comprises a base island 10 and a first pin 11 located outside the base island 10, the first pin 11 having a recess 111 in it. The conductive strip 15 further comprises a first welding part 154 located at the end of the bent part, the first welding part 154 being at least partially inserted into the recess 111 of the first pin 11 and electrically connected to the first pin 11.

Specifically, the first chip 13 is mounted on the base island 10 of the carrier board, and the first pins 11 are distributed in the first direction DI outside the base island 10. The first pin 11 has the recess 111 in it, and the first welding part 154 at the end of the conductive strip 15 is inserted into the recess 111 and welded to the first pin 11 by means of a filler layer 21. By providing the recess 111 in the first pin 11, thereby enabling the first welding portion 154 to be confined within the recess 111, this not only ensures the accuracy of the connection position of the conductive strip 15 and the first pin 11, but also increases the contact area between the conductive strip 15 and the first pin 11, and improves the strength of the connection between the conductive strip 15 and the first pin 11. In one example, the material of the filler layer 21 is solder.

In some embodiments, the carrier board further comprises a plurality of second pins 12 located outside the base island 10, at least a partial number of the second pins 12 being distributed in the second direction D2 on the side of the base island 10 facing away from the first pins 11. The first chip 13 is electrically connected to the second pin 12.

By way of example, as shown in FIGS. 1 and 2, the carrier board comprises a plurality of the second pins 12 located outside the base island 10. At least a partial number of the second pins 12 are located on the side of the base island 10 facing away from the first pin 11, and the first chip 13 is electrically connected to at least one of the second pins 12 located on the side of the base island 10 facing away from the first pin 11, thereby being able to help reduce signal crosstalk between the first pin 11 and the second pin 12. The plurality described in the present embodiment refers to two or more.

In some embodiments, the bent part of the conductive strip 15 further comprises a second planar segment 152 located above the second chip 14; the three-dimensional package structure further comprises a sensor 17, mounted to the second planar segment 152, and the sensor 17 is electrically connected to the carrier board.

By way of example, as shown in FIGS. 1 and 2, the bent part further comprises the second planar segment 152 extending in a direction parallel to the top surface of the carrier board (e.g., in the first direction D1), one end of the connection segment 153 is connected to the first planar segment 151 and the other end is connected to the second planar segment 152, and in the third direction D3, the second planar segment 152 is higher than the first planar segment 151, so that a step-like structure is formed by the first planar segment 151, the connection segment 153 and the second planar segment 152 together, wherein the first planar segment 151 and the second planar segment 152 are both horizontal table surfaces of the step-like structure. By using the second planar segment 152 in the conductive strip 15 as a mounting platform and mounting the sensor 17 on the second planar segment 152, not only is it possible to make full use of the internal space of the three-dimensional package structure and further improve the space utilization rate of the three-dimensional package structure, but also it is possible to monitor the external environment (i.e., the environment outside the three-dimensional package structure) by the sensor 17, thereby further extending the functions of the three-dimensional package structure. In one example, the sensor 17 is a temperature sensor. In one example, the sensor 17 is electrically connected to the second planar segment 152 in the conductive strip 15. In another example, the sensor 17 is electrically isolated from the conductive strip 15.

In some embodiments, the three-dimensional package structure further comprises a molding layer 22, the molding layer 22 molds the first chip 13, the second chip 14, the third chip 16, the conductive strip 15, and at least a partial of the sensor 17, and the detection end of the sensor 17 is exposed outside the molding layer 22.

Specifically, the molding layer 22 successively molds the first chip 13, the second chip 14, the third chip 16, the conductive strip 15, and at least a partial of the sensor 17, and the molding layer 22 fully fills the gaps between the base island 10 and the pins (comprising the first pin 11 and the second pin 12), as well as the gaps between adjacent pins (comprising the gaps between adjacent first pins 11, the gaps between adjacent second pins 12, and the gaps between the first pin 11 and the second pin 12). In one example, the material of the molding layer 22 may be an epoxy resin molding compound. The detection end of the sensor 17 (i.e., the end of the sensor 17 facing away from the conductive strip 15) is exposed outside the molding layer 22. On the one hand, it can improve the sensitivity and accuracy of the detection of the sensor 17; on the other hand, it also contributes to dissipating the heat inside the molding layer 22 (e.g., the heat generated by the first chip 13, the heat generated by the second chip 14, the heat generated by the third chip 16 and heat generated by the carrier board) to the outside, thereby improving the heat dissipation performance of the three-dimensional package structure.

In some embodiments, the three-dimensional package structure further comprises a conductive connection pillar, one end of the conductive connection pillar being electrically connected to the first chip 13 and the other end is electrically connected to the sensor 17. In some embodiments, the three-dimensional package structure further comprises a first bond wire 18, one end of the first bond wire 18 being electrically connected to the first chip 13 and the other end being electrically connected to the carrier board; a second bond wire 19, one end of the second bond wire 19 being electrically connected to the second chip 14 and the other end being electrically connected to the first chip 13; a third bond wire 20, one end of the third bond wire 20 being electrically connected to the third chip 16 and the other end being electrically connected to the first chip 13.

Specifically, the sensor 17 is electrically connected to the first chip 13 via the conductive connection pillar, and the first chip 13 is electrically connected to the carrier board via the first bond wire 18, thus enabling an electrical connection between the sensor 17 and the carrier board via the conductive connection pillar and the first chip 13. The second chip 14 can be electrically connected to the first chip 13 via the second bond wire 19, and can also be electrically connected to the carrier board via the conductive strip 15. The third chip 16 can be electrically connected to the first chip 13 via the third bond wire 20, and can also be electrically connected to the carrier board via the conductive strip 15. In one example, a plurality of electronic components are mounted onto the surface of the first chip 13, and the first bond wire 18, the second bond wire 19, and the third bond wire 20 are electrically connected to a different electronic component on the first chip 13, respectively. In one example, the first chip 13 may also be electrically connected to the first pin 11 via a fourth bond wire 23 to input different electrical signals to the first chip 13 via the first pin 11 and the second pin 12, respectively, thereby further extending the functions of the three-dimensional package structure.

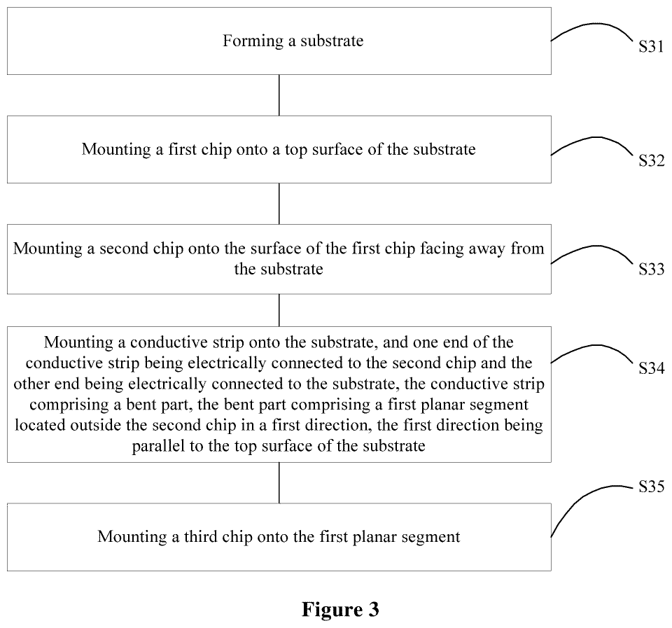

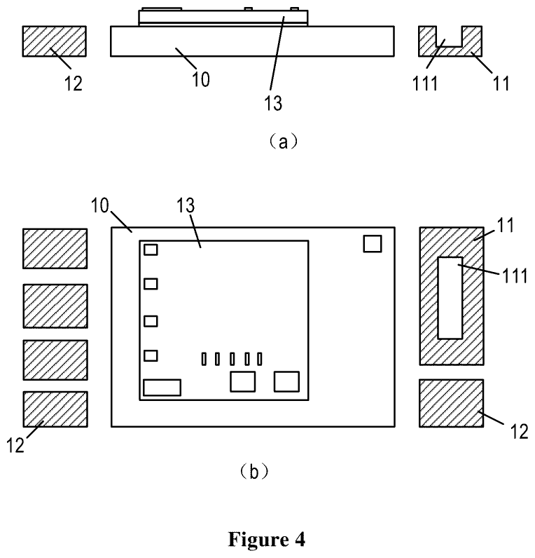

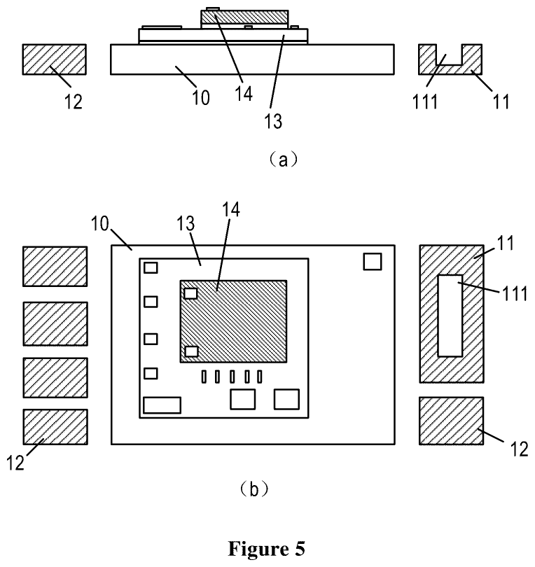

The present embodiment also provides a method for forming a three-dimensional package structure, FIG. 3 is a flowchart of a method for forming the three-dimensional package structure in some embodiments of the present disclosure, FIGS. 4-10 are schematic diagrams of the main process structures of the process for forming the three-dimensional package structure in some embodiments of the present disclosure. A schematic diagram of the three-dimensional package structure formed in the present embodiment can be seen in FIGS. 1 and 2. As shown in FIGS. 1-10, the method for forming a three-dimensional package structure, comprises the following steps.

At step S31, a carrier board is formed.

At step S32, a first chip 13 is mounted onto the top surface of the carrier board, as shown in FIG. 4, wherein (a) in FIG. 4 is a schematic sectional view after mounting the first chip 13 onto a top surface of the carrier board, and (b) in FIG. 4 is a schematic top view after mounting the first chip 13 onto the top surface of the carrier board.

At step S33, a second chip 14 is mounted onto a surface of the first chip 13 facing away from the carrier board, as shown in FIG. 5, wherein (a) in FIG. 5 is a schematic sectional view after mounting the second chip 14 onto the first chip 13, and (b) in FIG. 5 is a schematic top view after mounting the second chip 14 onto the first chip 13.

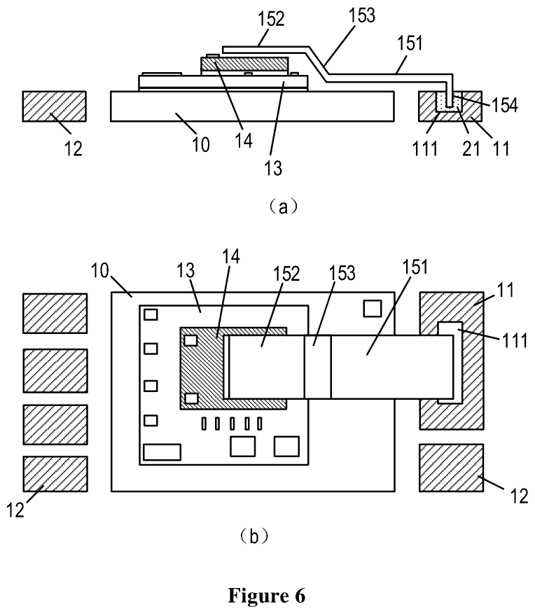

At step S34, a conductive strip 15 is mounted onto the carrier board, and one end of the conductive strip 15 is electrically connected to the second chip 14, and the other end is electrically connected to the carrier board, the conductive strip 15 comprising a bent part, the bent part comprising a first planar segment 151 located outside the second chip 14 in a first direction D1, the first direction DI being parallel to the top surface of the carrier board, as shown in FIG. 6, wherein (a) in FIG. 6 is a schematic sectional view after mounting the conductive strip 15 onto the carrier board, and (b) in FIG. 6 is a schematic top view after mounting the conductive strip 15 onto the carrier board.

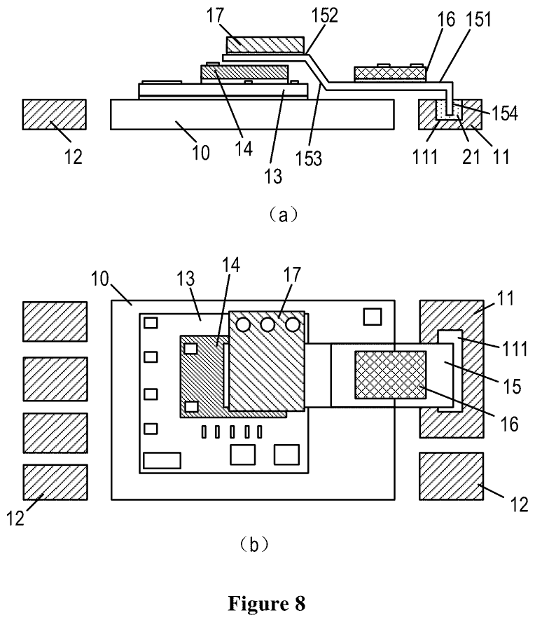

At step S35, the third chip 16 is mounted onto the first planar segment 151, as shown in FIG. 8, wherein (a) in FIG. 8 is a schematic sectional view after mounting the third chip 16 onto the first planar segment 151, and (b) in FIG. 8 is a schematic top view after mounting the third chip 16 onto the first planar segment 151.

In some embodiments, the carrier board comprises a base island 10 and a first pin 11 located outside the base island 10, the first pin 11 having a recess 111 in it; the specific steps of mounting the conductive strip 15 onto the carrier board comprise: forming a conductive strip 15, the conductive strip 15 further compriing a first welding part 154 and a second welding part located at opposite ends of the bent part; inserting the first welding part 154 into the recess 111 in the first pin 11, electrically connecting the first welding part 154 to the first pin 11 and electrically connecting the second welding part to the second chip 14.

By way of example, after forming the conductive strip 15, the first welding part 154 can be inserted into the recess 111 in the first pin 11, and a filling layer 21 can be formed by filling with solder or the like to realize the electrical connection between the conductive strip and the first pin 11. The second welding part is bonded and connected to the second chip 14, thereby realizing bridging between the second chip 14 and the carrier board by means of the conductive strip 15.

In some embodiments, the specific steps of mounting the third chip 16 onto the first planar segment 151 comprise mounting the third chip 16 onto the first planar segment 151 such that the third chip 16 is located outside the first chip 13 in the first direction DI.

Specifically, by adjusting the mounting position of the conductive strip 15 and the mounting position of the third chip 16 such that the projection of the third chip 16 on the top surface of the carrier board is located outside the projection of the first chip 13 on the top surface of the carrier board and the projection of the third chip 16 on the top surface of the carrier board is located outside the projection of the second chip 14 on the top surface of the carrier board, it is able to not only fully utilize the internal space of the three-dimensional package structure, but also to contribute to reducing the parasitic capacitance effect between the third chip 16 and the first chip 13 as well as the parasitic capacitance effect between the third chip 16 and the second chip 14.

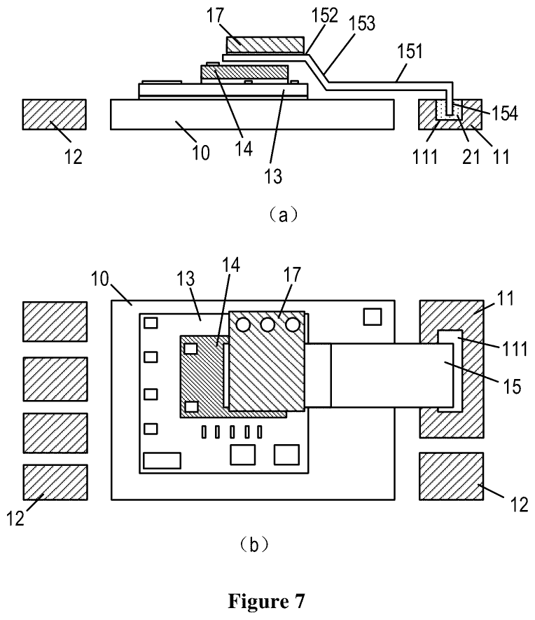

In some embodiments, the bent part in the conductive strip 15 further comprises a second planar segment 152 located above the second chip 14; further comprises the following steps: mounting a sensor 17 onto the second planar segment 152 and electrically connecting the sensor 17 to the carrier board, as shown in FIG. 7, wherein (a) in FIG. 7 is a schematic sectional view after mounting the sensor 17 onto the second planar segment 152, and (b) in FIG. 7 is a schematic top view after mounting the sensor 17 onto the second planar segment 152. In one example, the sensor 17 is a temperature sensor.

In some embodiments, specific steps for electrically connecting the sensor 17 to the carrier board comprise: electrically connecting the sensor 17 to one end of a conductive connection pillar, the other end of the conductive connection pillar being electrically connected to the first chip 13.

In some embodiments, after mounting the third chip 16 to the first planar segment 151, it further comprises the following steps: electrically connecting the first chip 13 to the carrier board and electrically connecting the third chip 16 to the carrier board.

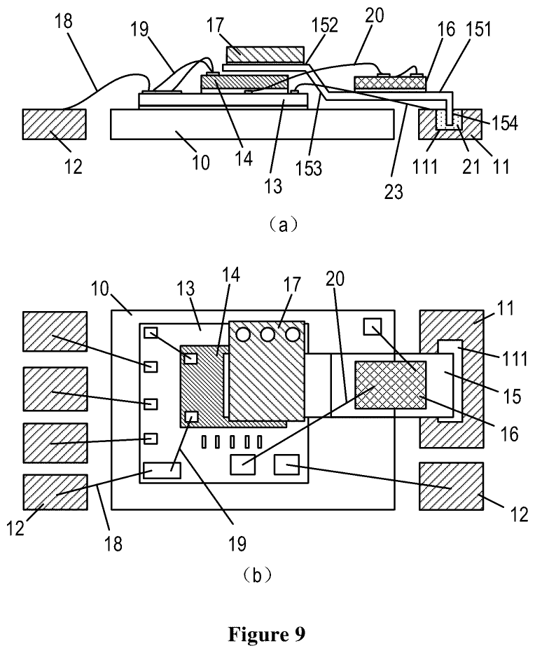

In some embodiments, the carrier board further comprises a plurality of second pins 12 located outside the base island 10, at least a partial number of the second pins 12 being distributed in the second direction D2 on the side of the base island 10 facing away from the first pin 11; the specific steps for electrically connecting the first chip 13 to the carrier board and electrically connecting the third chip 16 to the carrier board comprise: forming a first bond wire 18 electrically connecting the first chip 13 to the second pin 12, forming a second bond wire 19 electrically connecting the first chip 13 to the second chip 14, and forming a third bond wire 20 electrically connecting the first chip 13 to the third chip 16, as shown in FIG. 9, wherein (a) in FIG. 9 is a schematic sectional view after forming the first bond wire 18, the second bond wire 19, and the third bond wire 20, and (b) in FIG. 9 is a schematic top view after forming the first bond wire 18, the second bond wire 19, and the third bond wire 20. In one embodiment, a fourth bond wire 23 electrically connecting the first chip 13 to the first pin 11 may also be formed to input different electrical signals to the first chip 13 via the first pin 11 and the second pin 12, respectively, thereby further extending the functions of the three-dimensional package structure.

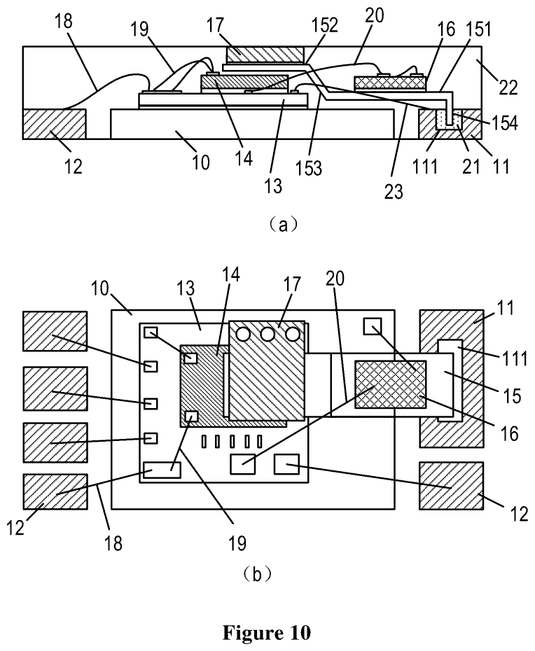

In some embodiments, after electrically connecting the first chip 13 to the carrier board, it further comprises the following steps: forming a molding layer that molds the first chip 13, the second chip 14, the third chip 16, the conductive strip 15, and at least a partial of the sensor 17, and the detection end of the sensor 17 is exposed outside the molding layer 17 as shown in FIG. 10, wherein (a) in FIG. 10 is a schematic sectional view after forming the molding layer 22, and (b) in FIG. 10 is a top schematic view after forming the plasticized layer 22. The detection end of the sensor 17 (i.e., the end of the sensor 17 facing away from the conductive strip 15) is exposed outside the molding layer 22. On the one hand, it can improve the sensitivity and accuracy of the detection of the sensor 17. On the other hand, it also contributes to dissipating the heat inside the molding layer 22 (e.g., the heat generated by the first chip 13, the heat generated by the second chip 14, the heat generated by the third chip 16 and heat generated by the carrier board) to the outside, thereby improving the heat dissipation performance of the three-dimensional package structure.

The three-dimensional package structure and the method for forming the same provided by the present disclosure, through the conductive strip with a bent part electrically connecting the second chip and the carrier board, and by using the first planar segment of the bent part as the mounting platform for the third chip, the third chip is mounted on the first planar segment. Since the first planar segment is located outside the second chip in a direction parallel to the top surface of the carrier board (e.g., the first direction), it enables the second chip and the third chip to be arranged in a direction parallel to the top surface of the carrier board, which not only makes full use of the internal space of the three-dimensional package structure, i.e., improves the space utilization rate inside the three-dimensional package structure. Moreover, by improving the space utilization rate inside the three-dimensional package structure, more semiconductor structures (e.g., chips, etc.) can also be integrated inside the three-dimensional package structure, thereby improving the integration degree of the three-dimensional package structure to meet the demand for integration of more package units as well as the extension of application scenarios.

The foregoing is only a preferred embodiment of the present disclosure, and it should be noted that for a person of ordinary skilled in the art, a number of improvements and variations may be made without departing from the principles of the present disclosure, and these improvements and variations should also be deemed to fall within the protection scope of the present disclosure.

What is claimed is:

1. A three-dimensional package structure, comprising:
a carrier board;
a first chip, located on a top surface of the carrier board;
a second chip, located on a side of the first chip facing away from the carrier board;
a conductive strip, located on the carrier board, one end of the conductive strip being electrically connected to the second chip and another other end being electrically connected to the carrier board, the conductive strip comprising a bent part, the bent part comprising a first planar segment located outside the second chip in a first direction, the first direction being parallel to the top surface of the carrier board; and
a third chip, mounted on the first planar segment.

2. The three-dimensional package structure according to claim 1, wherein in the first direction, the third chip is located outside the first chip.

3. The three-dimensional package structure according to claim 1, wherein
the carrier board comprises a base island and a first pin located outside the base island, the first pin having a recess in it; and
the conductive strip further comprises a first welding part located at the end of the bent part, the first welding part being at least partially inserted into the recess of the first pin and electrically connected to the first pin.

4. The three-dimensional package structure according to claim 3, wherein
the carrier board further comprises a plurality of second pins located outside the base island, at least a partial number of the second pins being distributed in a second direction on a side of the base island facing away from the first pin; and
the first chip is electrically connected to the second pin.

5. The three-dimensional package structure according to claim 3, wherein
the bent part of the conductive strip further comprises a second planar segment located above the second chip; and
the three-dimensional package structure further comprises a sensor, mounted on the second planar segment, the sensor being electrically connected to the carrier board.

6. The three-dimensional package structure according to claim 5, further comprising:
a molding layer,
wherein the molding layer molds the first chip, the second chip, the third chip, the conductive strip, and at least a partial of the sensor; and
a detection end of the sensor is exposed outside the molding layer.

7. The three-dimensional package structure according to claim 5, further comprising:
a conductive connection pillar, one end of the conductive connection pillar being electrically connected to the first chip and another other end being electrically connected to the sensor.

8. The three-dimensional package structure according to claim 1, further comprising:
a first bond wire, one end of the first bond wire being electrically connected to the first chip and another other end being electrically connected to the carrier board;
a second bond wire, one end of the second bond wire being electrically connected to the second chip and another end being electrically connected to the first chip; and
a third bond wire, one end of the third bond wire being electrically connected to the third chip and another other end being electrically connected to the first chip.

9. The three-dimensional package structure according to claim 5, wherein the sensor comprises a temperature sensor.

10. The three-dimensional package structure according to claim 1, wherein the first chip comprises a module chip or a functional chip, and the second chip comprises a control chip.

11. A method for forming a three-dimensional package structure, comprising:
forming a carrier board;
mounting a first chip onto a top surface of the carrier board;
mounting a second chip onto a surface of the first chip facing away from the carrier board;
mounting a conductive strip onto the carrier board, and one end of the conductive strip being electrically connected to the second chip and another other end being electrically connected to the carrier board, the conductive strip comprising a bent part, the bent part comprising a first planar segment located outside the second chip in a first direction, the first direction being parallel to the top surface of the carrier board; and
mounting a third chip onto the first planar segment.

12. The method for forming a three-dimensional package structure according to claim 11, wherein the carrier board comprises a base island and a first pin located outside the base island, the first pin having a recess in it; and mounting a conductive strip onto the carrier board comprises:
forming a conductive strip, the conductive strip further comprising a first welding part and a second welding part located at opposite ends of the bent part; and
inserting the first welding part into the recess in the first pin, electrically connecting the first welding part to the first pin and electrically connecting the second welding part to the second chip.

13. The method for forming a three-dimensional package structure according to claim 11, wherein mounting the third chip onto the first planar segment comprises:
mounting the third chip onto the first planar segment such that the third chip is located outside the first chip in the first direction.

14. The method for forming a three-dimensional package structure according to claim 11, wherein the bent part in the conductive strip further comprises a second planar segment located above the second chip; and forming a three-dimensional package structure further comprises:
mounting a sensor onto the second planar segment and electrically connecting the sensor to the carrier board.

15. The method for forming a three-dimensional package structure according to claim 14, wherein electrically connecting the sensor to the carrier board comprises:
electrically connecting the sensor to one end of a conductive connection pillar, another other end of the conductive connection pillar being electrically connected to the first chip.

16. The method for forming a three-dimensional package structure according to claim 12, further comprising, after mounting the third chip onto the first planar segment:
electrically connecting the first chip to the carrier board and electrically connecting the third chip to the carrier board.

17. The method for forming a three-dimensional package structure according to claim 16, wherein the carrier board further comprises a plurality of second pins located outside the base island, at least a partial number of the second pins being distributed in a second direction on a side of the base island facing away from the first pin; and electrically connecting the first chip to the carrier board and electrically connecting the third chip to the carrier board comprises:
forming a first bond wire electrically connecting the first chip to the second pin;
forming a second bond wire electrically connecting the first chip to the second chip; and
forming a third bond wire electrically connecting the first chip to the third chip.

18. The method for forming a three-dimensional package structure according to claim 14, further comprising, after electrically connecting the first chip to the carrier board:
forming a molding layer that molds the first chip, the second chip, the third chip, the conductive strip, and at least a partial of the sensor,
wherein a detection end of the sensor is exposed outside the molding layer.

19. The method for forming a three-dimensional package structure according to claim 15, wherein the sensor comprises a temperature sensor.

20. The method for forming a three-dimensional package structure according to claim 11, wherein the first chip comprises a module chip or a functional chip, and the second chip comprises a control chip.
